(19) United States
(12) Patent Application Publication
(10) Pub. No.: US 2025/0132733 A1
(43) Pub. Date: Apr. 24, 2025

(54) SELF-PROTECTION CIRCUITRY, CASCADE CIRCUIT, AND OPERATIONAL AMPLIFIER CIRCUIT

(71) Applicant: REALTEK SEMICONDUCTOR CORP., Hsinchu (TW)

(72) Inventors: Kuan-Hao Tseng, Hsinchu (TW); Hung-Yu Tsai, Hsinchu (TW); Po-Chih Wang, Hsinchu (TW)

(73) Assignee: REALTEK SEMICONDUCTOR CORP., Hsinchu (TW)

(21) Appl. No.: 18/918,738

(22) Filed: Oct. 17, 2024

(30) Foreign Application Priority Data
Oct. 20, 2023 (TW) 112140292

(51) Int. Cl. H03F 1/52; H03F 3/45

(52) U.S. Cl. CPC H03F 1/523; H03F 3/45269; H03F 2200/426

(57) ABSTRACT

A self-protection circuitry is configured to receive a first power source. The self-protection circuitry includes a first transistor circuit, a first switch circuit, and a control circuit. The first transistor circuit includes a first input terminal, a first output terminal, and a first control terminal. The first output terminal is electrically connected to a ground terminal, and the first input terminal is configured to receive the first power source. The first switch circuit is electrically connected to the first control terminal and the first input terminal. The control circuit is electrically connected to the first switch circuit, and is configured to: before the first power source supplies power to the first transistor circuit, control the first switch circuit to be 10 conducted, and after the first power source continuously supplies power to the first transistor circuit, control the first switch circuit to be cut off.

### CROSS-REFERENCE TO RELATED APPLICATION

This non-provisional application claims priority under 35 U.S.C. § 119(a) to Patent Application No. 112140292 filed in Taiwan, R.O.C. on Oct. 20, 2023, the entire contents of which are hereby incorporated by reference.

### BACKGROUND

### Technical Field

This solution relates to the field of circuit related technologies, and in particular, to a self-protection circuitry, a cascade circuit, and an operational amplifier circuit.

### Related Art

To avoid the impact of spikes on elements in a circuit, generally a parasitic capacitor is used to guide spikes to a ground terminal, or a semiconductor are used to guide reverse spikes to the ground terminal.

However, although the adverse impact caused by spikes can be avoided in the foregoing manner, when the circuit operates normally, because the parasitic capacitor or the semiconductor is still electrically connected to the circuit, the parasitic capacitor or the semiconductor affect the overall operation of the circuit, and protection can only be implemented against only one-way spikes.

### SUMMARY

In view of the foregoing, a self-protection circuitry is provided. In some embodiments, a self-protection circuitry is configured to receive a first power source. The self-protection circuitry includes a first transistor circuit, a first switch circuit, and a control circuit. A first transistor circuit includes a first input terminal, a first output terminal, and a first control terminal, where the first output terminal is electrically connected to a ground terminal, and the first input terminal is configured to receive the first power source. The first switch circuit is electrically connected to the first control terminal and the first input terminal. A control circuit is electrically connected to the first switch circuit, and is configured to: before the first power source supplies power to the first transistor circuit, control the first switch circuit to be conducted, and after the first power source continuously supplies power to the first transistor circuit, control the first switch circuit to be cut off.

In some embodiments, the control circuit controls, before the first power source stops supplying power to the first transistor circuit, the first switch circuit to be conducted.

In some embodiments, the self-protection circuitry further includes a second switch circuit and a third switch circuit. The second switch circuit is electrically connected between the first control terminal and the ground terminal. The third switch circuit is electrically connected between the first power source and the first input terminal. The control circuit is electrically connected to the second switch circuit and the third switch circuit, to control the second switch circuit and the third switch circuit to be separately conducted or cut off.

In some embodiments, the control circuit controls, before the first power source stops supplying power to the first transistor circuit, the first switch circuit to be conducted.

In some embodiments, the control circuit controls the second switch circuit and the third switch circuit to be both conducted, to enable the first power source to supply power to the first transistor circuit, and controls the second switch circuit and the third switch circuit to be both cut off, to prevent the first power source from supplying power to the first transistor circuit.

In some embodiments, the control circuit first controls, before controlling the third switch circuit to be conducted, the first switch circuit to be conducted.

A cascade circuit is further provided, and is configured to receive a first power source. The cascade circuit includes a first transistor circuit, a second transistor circuit, a first switch circuit, a second switch circuit, and a control circuit. The first transistor circuit includes a first input terminal, a first output terminal, and a first control terminal. The first input terminal receives the first power source. The second transistor circuit includes a second input terminal, a second output terminal, and a second control terminal. The first output terminal is electrically connected to the second input terminal, and the second output terminal is electrically connected to a ground terminal. The first switch circuit is electrically connected to the first control terminal and the first input terminal. The second switch circuit is electrically connected to the second control terminal and the second input terminal. The control circuit is electrically connected to the first switch circuit and the second switch circuit, and is configured to: before the first power source supplies power to the first transistor circuit, control the first switch circuit and the second switch circuit to be conducted, and after the first power source continuously supplies power to the first transistor circuit, control the first switch circuit and the second switch circuit to be cut off.

An operational amplifier circuit is further provided, and is configured to receive a first power source. The operational amplifier circuit includes a current mirror circuit, a first transistor circuit, a first switch circuit, and a control circuit. The first transistor circuit includes a first input terminal, a first output terminal, and a first control terminal. The first output terminal and the first control terminal are electrically connected to the current mirror circuit. The first input terminal is configured to receive the first power source. The first output terminal is electrically connected to a ground terminal. The first switch circuit is electrically connected to the first input terminal and the first control terminal. The control circuit is electrically connected to the first switch circuit, and is configured to: before the first power source supplies power to the first transistor circuit, control the first switch circuit to be conducted, and after the first power source continuously supplies power to the first transistor circuit, control the first switch circuit to be cut off.

### BRIEF DESCRIPTION OF THE DRAWINGS

FIG. 1 is a schematic circuit diagram of a self-protection circuitry according to some embodiments;

FIG. 2 is a schematic circuit diagram of a cascade circuit according to some embodiments;

FIG. 3 is a schematic circuit diagram of an operational amplifier circuit according to some embodiments;

FIG. 4 is a timing diagram of a first switch circuit, a second switch circuit, and a third switch circuit when a first power source supplies power according to some embodiments; and

FIG. 5 is a timing diagram of a first switch circuit, a second switch circuit, and a third switch circuit when a first power source is stopped according to some embodiments.

### DETAILED DESCRIPTION

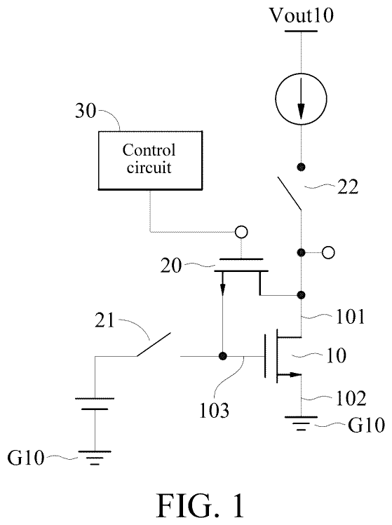

Referring to FIG. 1, a self-protection circuitry is configured to receive a first power source Vₒᵤₜ₁₀. The self-protection circuitry includes a first transistor circuit 10, a first switch circuit 20, and a control circuit 30.

Referring to FIG. 1, the first transistor circuit 10 includes a first input terminal 101, a first output terminal 102, and a first control terminal 103. The first input terminal 101 is configured to receive the first power source Vₒᵤₜ₁₀. The first output terminal 102 is electrically connected to a ground terminal G10. In some embodiments, the first transistor circuit 10 may be a bipolar junction transistor (BJT), or a field-effect transistor (FET). In some embodiments, the first transistor circuit 10 is an N channel enhancement MOSFET. The first input terminal 101 is a drain, the first output terminal 102 is a source, and the first control terminal 103 is a gate.

Referring to FIG. 1, the first switch circuit 20 is electrically connected to the first control terminal 103 and the first input terminal 101. In some embodiments, the first switch circuit 20 may be a bipolar junction transistor, or a field-effect transistor. In some embodiments, the first switch circuit 20 is an N channel enhancement MOSFET, a drain of the first switch circuit 20 is electrically connected to the first input terminal 101, and a source of the first switch circuit 20 is electrically connected to the first control terminal 103.

Referring to FIG. 1, the control circuit 30 is electrically connected to the first switch circuit 20, and is configured to: before the first power source Vₒᵤₜ₁₀ supplies power to the first transistor circuit 10, control the first switch circuit 20 to be conducted, and after the first power source Vₒᵤₜ₁₀ continuously supplies power to the first transistor circuit 10, control the first switch circuit 20 to be cut off. In some embodiments, the control circuit 30 is a control circuit such as a microprocessor, a digital signal processor (DSP), or an application-specific integrated circuit (ASIC) that can output a corresponding electrical signal.

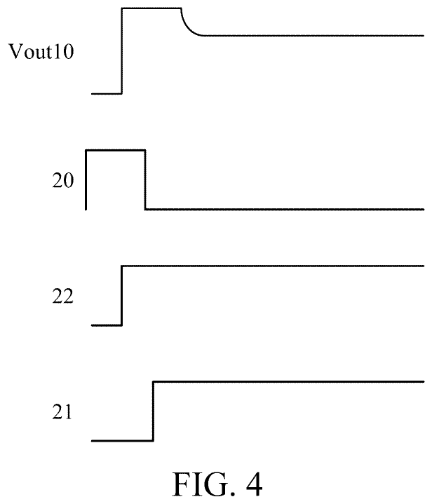

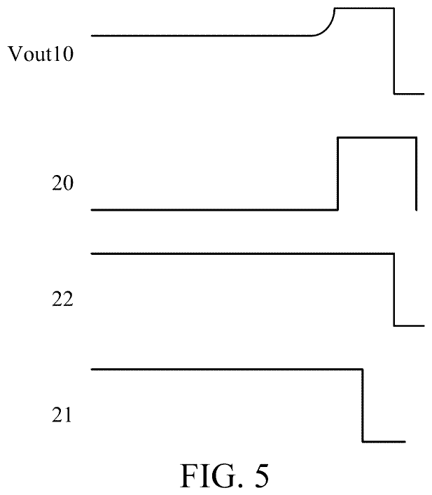

Referring to FIG. 1 and FIG. 4, before the first power source Vₒᵤₜ₁₀ supplies power to the first transistor circuit 10, the control circuit 30 first controls the first switch circuit 20 to form conduction. Therefore, when the first power source Vₒᵤₜ₁₀ starts to supply power to the first transistor circuit 10, a current first flows through the first switch circuit 20, then flows through the first transistor circuit 10 from the first control terminal 103, and is then outputted from the first output terminal 102. After the first power source Vₒᵤₜ₁₀ continuously supplies power to the first transistor circuit 10, the control circuit 30 controls the first switch circuit 20 to be cut off. In this case, when the first switch circuit 20 is conducted, the first transistor circuit 10 can be kept from damage due to an instantaneous excessively large current, and when the first switch circuit 20 is cut off, the first switch circuit 20 can be kept from affecting the overall circuit. Referring to FIG. 5, in some embodiments, before the first power source Vₒᵤₜ₁₀ stops supplying power to the first transistor circuit 10, the control circuit 30 first controls the first switch circuit 20 to be conducted, to keep spikes generated when power supply is stopped from affecting the first transistor circuit 10.

Referring to FIG. 1, in some embodiments, the self-protection circuitry further includes a second switch circuit 21 and a third switch circuit 22, and the second switch circuit 21 is electrically connected between the first control terminal 103 and the ground terminal G10. The third switch circuit 22 is electrically connected between the first power source Vₒᵤₜ₁₀ and the first input terminal 101. The control circuit 30 is electrically connected to the second switch circuit 21 and the third switch circuit 22, to control the second switch circuit 21 and the third switch circuit 22 to be separately conducted or cut off. When the second switch circuit 21 and the third switch circuit 22 form conduction, the first power source Vₒᵤₜ₁₀ can flow into the first transistor circuit 10, and when the second switch circuit 21 and the third switch circuit 22 form cutoff, the first power source Vₒᵤₜ₁₀ cannot flow into the first transistor circuit 10. Therefore, the control circuit 30 controls the second switch circuit 21 and the third switch circuit 22 to form conduction or cutoff, to determine whether the first power source Vₒᵤₜ₁₀ flows into the first transistor circuit 10. As discussed above, before the first power source Vₒᵤₜ₁₀ supplies power to the first transistor circuit 10 (that is, before the second switch circuit 21 and the third switch circuit 22 form conduction through the control of the control circuit 30), the first switch circuit 20 needs to be conducted first, and after the first power source Vₒᵤₜ₁₀ continuously supplies power to the first transistor circuit 10, the first switch circuit 20 forms cutoff. Similarly, before the first power source Vₒᵤₜ₁₀ stops supplying power to the first transistor circuit 10 (that is, before the second switch circuit 21 and the third switch circuit 22 form cutoff through the control of the control circuit 30), the first switch circuit 20 needs to form conduction first.

In some embodiments, through the control of the control circuit 30, at least the first switch circuit 20 needs to form conduction before the third switch circuit 22 forms conduction, regardless of whether the second switch circuit 21 has formed conduction before the first switch circuit 20 forms conduction. That is, a turn-on sequence of the first switch circuit 20, the second switch circuit 21, and the third switch circuit 22 may be the first switch circuit 20, the third switch circuit 22, and the second switch circuit 21, or the first switch circuit 20, the second switch circuit 21, and the third switch circuit 22. Alternatively, after the first switch circuit 20 is conducted, the second switch circuit 21 and the third switch circuit 22 simultaneously form conduction.

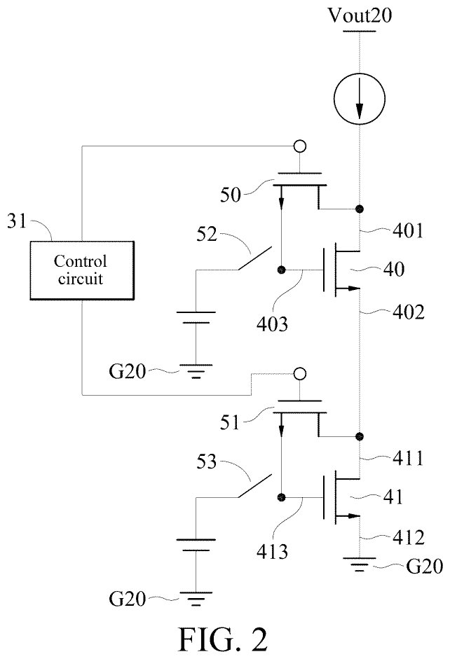

Referring to FIG. 2, in some embodiments, the self-protection circuitry may be applied to a cascade circuit. The cascade circuit is configured to receive a first power source Vₒᵤₜ₂₀. The cascade circuit includes a first transistor circuit 40, a second transistor circuit 41, a first switch circuit 50, a second switch circuit 51, and a control circuit 31.

Referring to FIG. 2, the first transistor circuit 40 includes a first input terminal 401, a first output terminal 402, and a first control terminal 403. The first input terminal 401 receives the first power source Vₒᵤₜ₂₀. The second transistor circuit 41 includes a second input terminal 411, a second output terminal 412, and a second control terminal 413. The first output terminal 402 is electrically connected to the second input terminal 411. The second output terminal 412 is electrically connected to a ground terminal G20. The first switch circuit 50 is electrically connected to the first control terminal 403 and the first input terminal 401. The second switch circuit 51 is electrically connected to the second control terminal 413 and the second input terminal 411. The control circuit 31 is electrically connected to the first switch circuit 50 and the second switch circuit 51, and is configured to: before the first power source Vₒᵤₜ₂₀ supplies power to the first transistor circuit 40, control the first switch circuit 50 and the second switch circuit 51 to be conducted, and after the first power source Vₒᵤₜ₂₀ continuously supplies power to the first transistor circuit 40, control the first switch circuit 50 and the second switch circuit 51 to be cut off.

Before the first power source Vₒᵤₜ₂₀ supplies power to the first transistor circuit 40, the first switch circuit 50 and the second switch circuit 51 need to be conducted first. After the first power source Vₒᵤₜ₂₀ continuously supplies power to the first transistor circuit 40, the first switch circuit 50 and the second switch circuit 51 form cutoff. Therefore, the first power source Vₒᵤₜ₂₀ first flows through the first switch circuit 50, then flows through the first transistor circuit 40 from the first control terminal 403, and is outputted from the first output terminal 402. Next, the first power source Vₒᵤₜ₂₀ flows through the second switch circuit 51, and is then outputted from the second output terminal 412 by the second control terminal 413 through the second transistor circuit 41. In this way, it is avoided that the first power source Vₒᵤₜ₂₀ causes damage to the first transistor circuit 40 and the second transistor circuit 41 when starting to supply power. In addition, when the first power source Vₒᵤₜ₂₀ continuously supplies power to the first transistor circuit 40 and the second transistor circuit 41, the control circuit 31 then controls the first switch circuit 50 and the second switch circuit 51 to be cut off. It is avoided that the first switch circuit 50 and the second switch circuit 51 affect the operation of the cascade circuit.

In some embodiments, the control circuit 31 is configured to: before the first power source Vₒᵤₜ₂₀ stops supplying power to the first transistor circuit 40, control the first switch circuit 50 and the second switch circuit 51 to be conducted. In this way, it is avoided that spikes generated when the first power source Vₒᵤₜ₂₀ stops supplying power affect the cascade circuit.

In some embodiments, the cascade circuit includes a third switch circuit 52 and a fourth switch circuit 53. The third switch circuit 52 is electrically connected between the first control terminal 403 and the ground terminal G20. The fourth switch circuit 53 is electrically connected between the second control terminal 413 and the ground terminal G20. The control circuit 31 is electrically connected to the third switch circuit 52 and the fourth switch circuit 53. The control circuit 31 is configured to control the third switch circuit 52 and the fourth switch circuit 53 to be separately conducted or cut off.

In some embodiments, through the control of the control circuit 31, at least the first switch circuit 50 and the second switch circuit 51 need to need to form conduction before the third switch circuit 52 and the fourth switch circuit 53 form conduction. That is, a turn-on sequence of the first switch circuit 50, the second switch circuit 51, the third switch circuit 52, and the fourth switch circuit 53 may be the first switch circuit 50, the second switch circuit 51, the third switch circuit 52, and the fourth switch circuit 53. Alternatively, the third switch circuit 52 and the fourth switch circuit 53 simultaneously form conduction after the first switch circuit 50 and the second switch circuit 51 simultaneously form conduction.

In some embodiments, the first switch circuit 50, the second switch circuit 51, the third switch circuit 52, the fourth switch circuit 53, the first transistor circuit 40, and the second transistor circuit 41 may be bipolar junction transistors, or field-effect transistors. In some embodiments, the first switch circuit 50, the second switch circuit 51, the third switch circuit 52, the fourth switch circuit 53, the first transistor circuit 40, and the second transistor circuit 41 are N channel enhancement MOSFETs, the first input terminal 401 and the second input terminal 411 are drains, the first output terminal 402 and the second output terminal 412 are sources, and the first control terminal 403 and the second control terminal 413 are gates.

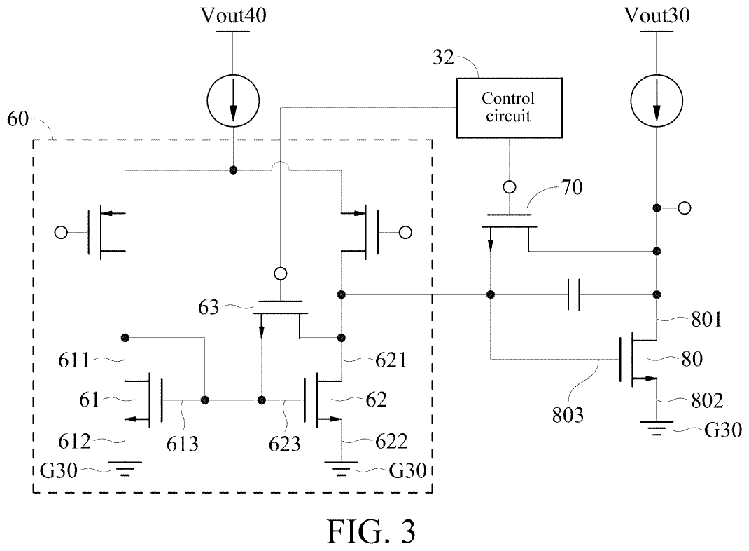

Referring to FIG. 3, in some embodiments, the self-protection circuitry may be applied to an operational amplifier circuit. The operational amplifier circuit is configured to receive a first power source Vₒᵤₜ₃₀, and the operational amplifier circuit includes a current mirror circuit 60, a first switch circuit 70, a first transistor circuit 80, and a control circuit 32.

The first transistor circuit 80 includes a first input terminal 801, a first output terminal 802, and a first control terminal 803. The first input terminal 801 and the first control terminal 803 are electrically connected to the current mirror circuit 60. The first input terminal 801 is configured to receive the first power source Vₒᵤₜ₃₀. The first output terminal 802 is electrically connected to a ground terminal G30. The first switch circuit 70 is electrically connected to the first input terminal 801 and the first control terminal 803. The control circuit 32 is electrically connected to the first switch circuit 70, and is configured to: before the first power source Vₒᵤₜ₃₀ supplies power to the first transistor circuit 80, control the first switch circuit 70 to be conducted, and after the first power source Vₒᵤₜ₃₀ continuously supplies power to the first transistor circuit 80, control the first switch circuit 70 to be cut off.

Before the operational amplifier circuit receives the first power source Vₒᵤₜ₃₀, the control circuit 32 first controls the first switch circuit 70 to be conducted, so that after flowing through the first switch circuit 70, the first power source Vₒᵤₜ₃₀ flows through the first transistor circuit 80 via the first control terminal 803 to flow into the ground terminal G30 from the first output terminal 802, to avoid that when starting to supply power to the operational amplifier circuit, the first power source Vₒᵤₜ₃₀ causes adverse impact to elements inside the operational amplifier circuit. When the first power source Vₒᵤₜ₃₀ continuously supplies power to the operational amplifier circuit, the control circuit 32 controls the first switch circuit 70 to form cutoff, to keep the first switch circuit 70 from affecting the operation of the operational amplifier circuit.

In some embodiments, before the first power source Vₒᵤₜ₃₀ stops supplying power to the operational amplifier circuit, the control circuit 32 controls the first switch circuit 70 to form conduction, to avoid that spikes generated when the first power source Vₒᵤₜ₃₀ stops supplying power cause adverse impact to the operational amplifier circuit.

In some embodiments, the current mirror circuit 60 is configured to receive a second power source Vₒᵤₜ₄₀. The current mirror circuit 60 includes a second transistor circuit 61, a third transistor circuit 62, and a second switch circuit 63. The second transistor circuit 61 includes a second input terminal 611, a second output terminal 612, and a second control terminal 613. The second control terminal 613 is electrically connected to the second input terminal 611. The second input terminal 611 is configured to receive the second power source Vₒᵤₜ₄₀. The second output terminal 612 is electrically connected to the ground terminal G30. The third transistor circuit 62 includes a third input terminal 621, a third output terminal 622, and a third control terminal 623. The second control terminal 613 is electrically connected to the third control terminal 623. The third input terminal 621 is configured to receive the second power source Vₒᵤₜ₄₀. The third output terminal 622 is electrically connected to the ground terminal G30. The second switch circuit 63 is electrically connected to the third control terminal 623 and the third input terminal 621. The control circuit 32 is electrically connected to the second switch circuit 63, and is configured to: before the second power source Vₒᵤₜ₄₀ supplies power to the current mirror circuit 60, control the second switch circuit 63 to be conducted, and after the second power source Vₒᵤₜ₄₀ continuously supplies power to the current mirror circuit 60, control the second switch circuit 63 to be cut off.

Before the current mirror circuit 60 starts to receive the second power source Vₒᵤₜ₄₀, the control circuit 32 first controls the second switch circuit 63 to form conduction. Therefore, when the second power source Vₒᵤₜ₄₀ enters the current mirror circuit 60, after flowing through the third control terminal 623 along the second switch circuit 63, the second power source Vₒᵤₜ₄₀ passes through the third transistor circuit 62 and finally flows to the ground terminal G30 from the third output terminal 622. In this way, it is avoided at the instant when the second power source Vₒᵤₜ₄₀ enters the current mirror circuit 60, the second transistor circuit 61 or the third transistor circuit 62 is damaged. After the second power source Vₒᵤₜ₄₀ continuously supplies power to the current mirror circuit 60, the control circuit 32 controls the second switch circuit 63 to form cutoff, to reduce the impact of the second switch circuit 63 on the operations of the current mirror circuit 60.

In addition, in some embodiments, before the second power source Vₒᵤₜ₄₀ stops supplying power to the current mirror circuit 60, the control circuit 32 controls the second switch circuit 63 to form conduction, to avoid that spikes generated when the second power source Vₒᵤₜ₄₀ stops supplying power cause adverse impact to the current mirror circuit 60.

In some embodiments, the first transistor circuit 80, the second transistor circuit 61, the third transistor circuit 62, the first switch circuit 70, and the second switch circuit 63 may be bipolar junction transistors, or field-effect transistors. In some embodiments, the first transistor circuit 80, the second transistor circuit 61, the third transistor circuit 62, the first switch circuit 70, and the second switch circuit 63 are all N channel enhancement MOSFETs. The first input terminal 801, the second input terminal 611, and the third input terminal 621 are all drains. The first output terminal 802, the second output terminal 612, and the third output terminal 622 are all sources. The first control terminal 803, the second control terminal 613, and the third control terminal 623 are all gates.

According to the self-protection circuitry in some embodiments of this solution, the control circuit 30 is used to control the first switch circuit 20 to be conducted or cut off, so that when the self-protection circuitry starts to receive the first power source Vₒᵤₜ₁₀, or stops receiving the first power source Vₒᵤₜ₁₀, the first switch circuit 20 is used to form conduction to provide the self-protection circuitry with a self-protection function. When the self-protection circuitry continuously receives the first power source Vₒᵤₜ₁₀, the first switch circuit 20 forms cutoff, to keep the first switch circuit 20 from affecting the operation of the self-protection circuitry.

What is claimed is:

1. A self-protection circuitry, configured to receive a first power source, and comprising:
a first transistor circuit, comprising a first input terminal, a first output terminal, and a first control terminal, wherein the first output terminal is electrically connected to a ground terminal, and the first input terminal is configured to receive the first power source;
a first switch circuit, electrically connected to the first control terminal and the first input terminal; and
a control circuit, electrically connected to the first switch circuit, and configured to: before the first power source supplies power to the first transistor circuit, control the first switch circuit to be conducted, and after the first power source continuously supplies power to the first transistor circuit, control the first switch circuit to be cut off.

2. The self-protection circuitry according to claim 1, wherein the control circuit controls, before the first power source stops supplying power to the first transistor circuit, the first switch circuit to be conducted.

3. The self-protection circuitry according to claim 1, further comprising:
a second switch circuit, electrically connected between the first control terminal and the ground terminal; and
a third switch circuit, electrically connected between the first power source and the first input terminal,
wherein the control circuit is electrically connected to the second switch circuit and the third switch circuit, to control the second switch circuit and the third switch circuit to be separately conducted or cut off.

4. The self-protection circuitry according to claim 3, wherein the control circuit controls, before the first power source stops supplying power to the first transistor circuit, the first switch circuit to be conducted.

5. The self-protection circuitry according to claim 3, wherein the control circuit controls the second switch circuit and the third switch circuit to be both conducted, to enable the first power source to supply power to the first transistor circuit, and controls the second switch circuit and the third switch circuit to be both cut off, to prevent the first power source from supplying power to the first transistor circuit.

6. The self-protection circuitry according to claim 3, wherein the control circuit first controls, before controlling the third switch circuit to be conducted, the first switch circuit to be conducted.

7. A cascade circuit, configured to receive a first power source, and comprising:
a first transistor circuit, comprising a first input terminal, a first output terminal, and a first control terminal, wherein the first input terminal receives the first power source;
a second transistor circuit, comprising a second input terminal, a second output terminal, and a second control terminal, wherein the first output terminal is electrically connected to the second input terminal, and the second output terminal is electrically connected to a ground terminal;
a first switch circuit, electrically connected to the first control terminal and the first input terminal;
a second switch circuit, electrically connected to the second control terminal and the second input terminal; and
a control circuit, electrically connected to the first switch circuit and the second switch circuit, and configured to: before the first power source supplies power to the first transistor circuit, control the first switch circuit and the second switch circuit to be conducted, and after the first power source continuously supplies power to the first transistor circuit, control the first switch circuit and the second switch circuit to be cut off.

8. The cascade circuit according to claim 7, wherein the control circuit is configured to: before the first power source stops supplying power to the first transistor circuit, control the first switch circuit and the second switch circuit to be conducted.

9. The cascade circuit according to claim 8, comprising:
a third switch circuit, electrically connected between the first control terminal and the ground terminal; and
a fourth switch circuit, electrically connected between the second control terminal and the ground terminal,
wherein the control circuit is electrically connected to the third switch circuit and the fourth switch circuit, and the control circuit is configured to control the third switch circuit and the fourth switch circuit to be separately conducted or cut off.

10. An operational amplifier circuit, configured to receive a first power source, and comprising:
a current mirror circuit;
a first transistor circuit, comprising a first input terminal, a first output terminal, and a first control terminal, wherein the first input terminal and the first control terminal are electrically connected to the current mirror circuit, the first input terminal is configured to receive the first power source, and the first output terminal is electrically connected to a ground terminal;
a first switch circuit, electrically connected to the first input terminal and the first control terminal; and
a control circuit, electrically connected to the first switch circuit, and configured to: before the first power source supplies power to the first transistor circuit, control the first switch circuit to be conducted, and after the first power source continuously supplies power to the first transistor circuit, control the first switch circuit to be cut off.

11. The operational amplifier circuit according to claim 10, wherein the control circuit controls, before the first power source stops supplying power to the first transistor circuit, the first switch circuit to be conducted.

12. The operational amplifier circuit according to claim 10, wherein the current mirror circuit is configured to receive a second power source, and the current mirror circuit comprises:
a second transistor circuit, comprising a second input terminal, a second control terminal, and a second output terminal, wherein the second control terminal is electrically connected to the second input terminal, the second input terminal is configured to receive the second power source, and the second output terminal is electrically connected to the ground terminal;
a third transistor circuit, comprising a third input terminal, a third control terminal, and a third output terminal, wherein the second control terminal is electrically connected to the third control terminal, the third input terminal is configured to receive the second power source, and the third output terminal is electrically connected to the ground terminal; and
a second switch circuit, electrically connected to the third control terminal and the third input terminal,
wherein the control circuit is electrically connected to the second switch circuit, and is configured to: before the second power source supplies power to the current mirror circuit, control the second switch circuit to be conducted, and after the second power source continuously supplies power to the current mirror circuit, control the second switch circuit to be cut off.

13. The operational amplifier circuit according to claim 12, wherein the control circuit controls, before the second power source stops supplying power to the current mirror circuit, the second switch circuit to be conducted.
